(19) United States
(12) Patent Application Publication
(10) Pub. No.: US 2013/0335936 A1
(43) Pub. Date: Dec. 19, 2013

(54) INTERPOSER SUBSTRATE, ELECTRONIC DEVICE PACKAGE, AND ELECTRONIC COMPONENT

(71) Applicant: FUJIKURA LTD., TOKYO (JP)

(72) Inventors: Satoshi YAMAMOTO, Sakura-shi (JP); Hiroyuki WAKIOKA, Sakura-shi (JP)

(73) Assignee: FUJIKURA LTD., TOKYO (JP)

(21) Appl. No.: 13/968,886

(22) Filed: Aug. 16, 2013

Related U.S. Application Data
(63) Continuation of application No. PCT/JP2012/062157, filed on May 11, 2012.

(30) Foreign Application Priority Data
May 12, 2011 (JP) 2011-107580

(51) Int. Cl. H05K 1/11; H05K 7/00

(52) U.S. Cl. CPC H05K 1/115; H05K 7/005
USPC 361/760; 174/262; 174/252

(57) ABSTRACT

An interposer substrate of the invention includes: a single substrate having a first main surface and a second main surface; and a plurality of through-hole interconnections having first portions formed so as to extend in parallel with each other and connecting the first main surface to the second main surface, wherein the through-hole interconnections adjacent to each other are provided so that ideal axes are parallel to each other with a distance therebetween, and the ideal axes extend perpendicular to at least one of the first main surface and the second main surface and penetrate through centers of the first portions.

### CROSS REFERENCE TO RELATED APPLICATIONS

This application is a continuation application based on a PCT Patent Application No. PCT/JP2012/062157, filed May 11, 2012, whose priority is claimed on Japanese Patent Application No. 2011-107580 filed on May, 12, 2011, the content of which is hereby incorporated by reference.

### BACKGROUND OF THE INVENTION

1. Field of the Invention

The present invention relates to an interposer substrate, an electronic device package using the same, and an electronic component which are provided with through-hole interconnections realizing a SiP (system in package) in which a high-density package such as an electronic device, an optical device, a MEMS device, or the like or such devices are systemized in a single package.

2. Description of the Related Art

In recent years, with the higher performance of electronic devices such as portable telephones or the like, higher speed and higher performance are required for electronic devices or the like used therein.

In order to achieve this, technological development is necessary for realizing not only a higher-speed and higher-performance device but also a higher-density wiring of a device package by miniaturizing a wiring pattern or the like.

As a technique of high-density packaging, a SiP is proposed which uses a three-dimensional packaging technique of stacking and packaging chips by use of microscopic through-hole interconnections or uses an interposer substrate in which through-hole interconnections are formed.

Formation techniques of through-hole interconnections or an interposer substrate used for realizing a SiP have been actively researched and developed.

In an interposer substrate which is provided with a conventional through-hole interconnection formed in the direction perpendicular to a main surface of a substrate, when a plurality of substrates are arranged so as to be stacked in layers, an interposer electrode may be removed and pulled therefrom by being damaged by an external force during connection or a boundary separation may occur.

Japanese Patent No. 3896038 is disclosed in which an interposer substrate is provided with a through-hole interconnection formed and inclined to a direction perpendicular to a main surface of a substrate in order to solve such problems.

When highly-densified three-dimensional packaging is carried out by use of a plurality of through-hole interconnections in the above-described interposer substrate, there are technical problems.

A configuration example of a conventional interposer substrate will be described with reference to FIGS. 13 to 15 schematically showing that.

Here, FIG. 13 is a plan view illustrating a state where a plurality of terminal groups are arranged on the surface of a conventional interposer substrate.

Moreover, FIG. 14 is a cross-sectional view taken along the line M4-M4 shown in FIG. 13 and FIG. 15 is a cross-sectional view taken along the line N4-N4 shown in FIG. 13.

As a structure, it is thought that, for example, a plurality of terminals 130A, 130B, and 130C arranged at equal distance on the first main surface 110a of the substrate 110 are electrically connected to a plurality of terminals 130A′, 130B′, and 130C′ arranged on the second main surface 110b of the substrate 110 through the through-hole interconnections 120A, 120B, and 120C, respectively, so that the terminal numbers thereof correspond to each other as shown in FIGS. 13 and 14. Specifically, the terminals 130A′, 130B′, and 130C′ are arranged on the second main surface 110b of the substrate 110 with the same layout as that of the terminals 130A, 130B, and 130C.

The positions of the terminals 130A′, 130B′, and 130C′ on the second main surface 110b are different from the positions of the terminals 130A, 130B, and 130C in the X direction.

Here, the diameters R of the through-hole interconnections are constant as shown in FIG. 15, and the distances L between adjacent through-hole interconnections (the distance between edges of the through-hole interconnections) are also constant.

At this time, it is apparent from FIG. 15 that the through-hole interconnections 120A, 120B, and 120C linearly align at equal distance inside the substrate 110 in the thickness direction of the substrate, and the thickness of the substrate 110 increases with increasing the number of the through-hole interconnections.

However, in order to avoid a malfunction, which is caused by mutual interference, while maintaining electrical insulation between the adjacent through-hole interconnections, it is not possible to decrease the distance L between the separate through-hole interconnections without limitation.

Consequently, when the number of through-hole interconnections increases with an increase in the number of terminals of a device to be packaged, the thickness of the substrate thereby increases.

Such increase in the substrate thickness is undesirable in terms of downsizing and thinning of a high-density package.

### SUMMARY OF THE INVENTION

The invention was made in order to solve the above conventional problems and has a first object thereof to provide an interposer substrate which can suppress an increase in the thickness of the substrate even when the number of through-hole interconnections increases, has a high degree of freedom in design of a wiring structure, and can realize downsized and highly-densified three-dimensional packaging.

Additionally, the invention has a second object to provide an electronic device package which has a high degree of freedom in design of a wiring structure and can realize downsized and highly-densified three-dimensional packaging.

Furthermore, the invention has a third object to provide an electronic component which has a high degree of freedom in design of a wiring structure and can realize downsized and highly-densified three-dimensional packaging.

In order to achieve the object, an interposer substrate of a first aspect of the invention includes: a single substrate having a first main surface and a second main surface; and a plurality of through-hole interconnections having first portions formed so as to extend in parallel with each other and connecting the first main surface to the second main surface, wherein the through-hole interconnections adjacent to each other are provided so that ideal axes are parallel to each other with a distance therebetween, and the ideal axes extend perpendicular to at least one of the first main surface and the second main surface and penetrate through centers of the first portions.

According to the interposer substrate of the first aspect of the invention, when the axes (ideal axis) are supposed which are vertical to a main surface of the substrate and penetrating through the centers of the horizontal cross-sectional faces of the first portions, the through-hole interconnections adjacent to each other are displaced from each other so that both axes are parallel with a distance therebetween.

Consequently, as compared with the structure in which through-hole interconnections align so as not to be displaced from the direction perpendicular to the main surface so that the through-hole interconnections having the same number as that of the first aspect of the invention are separated from each other at the same distance, it is possible to suppress an increase in the thickness of the substrate of the through-hole interconnections in the interposer substrate of the first aspect of the invention.

As a result, according to the invention, even where the number of through-hole interconnections increases, an increase in the thickness of the substrate can be suppressed, a high degree of freedom in design of a wiring structure, and furthermore, it is possible to provide a downsized interposer substrate provided with through-hole interconnections which can realize highly-densified three-dimensional packaging.

In the interposer substrate of the first aspect of the invention, it is preferable that the first portions be located substantially parallel to at least one of the first main surface and the second main surface.

Consequently, since the positions of the first portions are always constant in the depth direction of the substrate, it is possible to effectively suppress an increase in the thickness of the substrate in the thickness direction.

In the interposer substrate of the first aspect of the invention, it is preferable that the through-hole interconnections have second portions and third portions forming both ends of the first portions, longitudinal directions of the second portions be substantially perpendicular to the first main surface, and longitudinal directions of the third portions be substantially perpendicular to the second main surface.

For this reason, even in the cases where the initial thickness of the substrate varies or the thickness thereof varies depending on processing accuracy in a step of polishing the substrate, since the positions of the opening portions provided at the main surface of the interposer substrate do not vary, it is possible to reliably form the through-hole interconnections with a high level of accuracy.

In the interposer substrate of the first aspect of the invention, it is preferable that lengths of the through-hole interconnections are the same as each other.

By means of this structure, the electrical resistances of the through-hole interconnections can be substantially uniform.

Particularly, since variations in the interconnection resistances between the through-hole interconnections can be reduced, the invention results in stabilization of electrical characteristics of the device which is mounted onto the interposer substrate.

It is preferable that the interposer substrate of the first aspect of the invention further include: pads provided on the first main surface so as to be electrically connected to the second portions constituting the through-hole interconnections; and pads provided on the second main surface so as to be electrically connected to the third portions constituting the through-hole interconnections.

Accordingly, when devices are mounted onto, for example, both faces of the interposer substrate, since the electrodes of the devices and the pads are electrically connected to each other without front wirings, the connection between the substrate and the devices (electronic components) is facilitated and the electrodes and both devices can be connected in substantially the shortest route.

Furthermore, according to the invention, even in cases where, for example, a downsized device in which the electrodes are densely arranged with any layout is used, since the design of the pads can be freely modified so as to match the positions of the electrodes of a device, it is possible to package the downsized device into the interposer substrate.

In the interposer substrate of the first aspect of the invention, it is preferable that the substrate include a cooling unit cooling the substrate.

For this reason, even in cases where, for example, electrodes are high-densely arranged and a device having a large amount of heat generation is mounted onto the interposer substrate, an increase in temperature can be effectively reduced.

An electronic device package of a second aspect of the invention includes: the interposer substrate of the aforementioned first aspect and an electronic device mounted onto at least one of the first main surface and the second main surface of the interposer substrate.

As a result, it is possible to make an electronic device including the electronic device package thinner, and to realize downsizing thereof, speeding up thereof, or the like.

It is preferable that the through-hole interconnections of the interposer substrate have second portions and third portions forming both ends of the first portions, at least one of an end portion of the second portions and an end portion of the third portions be located at a position facing a terminal of the electronic device, and the terminal of the electronic device be electrically connected to at least one of the end portions of the second portions and the third portions.

By means of this structure, even in cases where a downsized device in which the electrodes are densely arranged with any layout is used, since the electrodes and the pads of the device mounted onto the interposer substrate are electrically connected to each other without front wirings, it is possible to freely connect the electrodes of the device to the pads.

Furthermore, in the case of the package in which devices are mounted onto both faces of the substrate, since the end portions of the second portion and the third portion are arranged so as to face the terminals of the device, respectively, and they can be electrically connected to each other, it is possible to connect both the electrodes of the device each other in substantially the shortest route, it is possible to provide a downsized electronic device package which has high-performances.

An electronic component of a third aspect of the invention includes the electronic device package of the aforementioned second aspect.

As a result, it is possible to make an electronic device including the electronic device package (electronic component) thinner, and to realize downsizing thereof, speeding up thereof, or the like.

### EFFECTS OF THE INVENTION

According to the invention results in downsized and highly-densified three-dimensional packaging which can suppress an increase in the thickness of the substrate even where the number of through-hole interconnections increases, and has a high degree of freedom in design of a wiring structure.

Additionally, according to the invention, it is possible to provide an electronic device package which has a high degree of freedom in design of a wiring structure and to realize downsized and highly-densified three-dimensional packaging.

Moreover, according to the invention, it is possible to provide an electronic component which has a high degree of freedom in design of a wiring structure and to realize downsized and highly-densified three-dimensional packaging.

### BRIEF DESCRIPTION OF THE DRAWINGS

FIG. 1 is a plan view schematically showing an interposer substrate of a first embodiment of the invention.

FIG. 2 is a cross-sectional view taken along the line M1-M1 shown in FIG. 1.

FIG. 3 is a cross-sectional view taken along the line N1-N1 shown in FIG. 1.

FIG. 4 is an enlarged cross-sectional view illustrating placement of through-hole interconnections of the interposer substrate of the first embodiment of the invention.

FIG. 5 is a cross-sectional view schematically showing an interposer substrate of a second embodiment of the invention.

FIG. 6 is a cross-sectional view schematically showing an interposer substrate of a fourth embodiment of the invention.

FIG. 7 is a cross-sectional view taken along the line M2-M2 shown in FIG. 6.

FIG. 8 is a cross-sectional view taken along the line N2-N2 shown in FIG. 6.

FIG. 9A is a schematic cross-sectional view illustrating a step of a method of manufacturing an interposer substrate.

FIG. 9B is a schematic cross-sectional view illustrating a step of a method of manufacturing an interposer substrate.

FIG. 9C is a schematic cross-sectional view illustrating a step of a method of manufacturing an interposer substrate.

FIG. 9D is a schematic cross-sectional view illustrating a step of a method of manufacturing an interposer substrate.

FIG. 10 is a plan view schematically showing an example of an electronic device package of the invention.

FIG. 11 is a cross-sectional view taken along the line M3-M3 shown in FIG. 10.

FIG. 12 is a cross-sectional view taken along the line N3-N3 shown in FIG. 10.

FIG. 13 is a plan view schematically showing an example of a conventional interposer substrate.

FIG. 14 is a cross-sectional view taken along the line M4-M4 shown in FIG. 13.

FIG. 15 is a cross-sectional view taken along the line N4-N4 shown in FIG. 13.

### DETAILED DESCRIPTION OF THE INVENTION

Hereinafter, preferred embodiments of an interposer substrate of the invention will be described with reference to drawings.

### First Embodiment

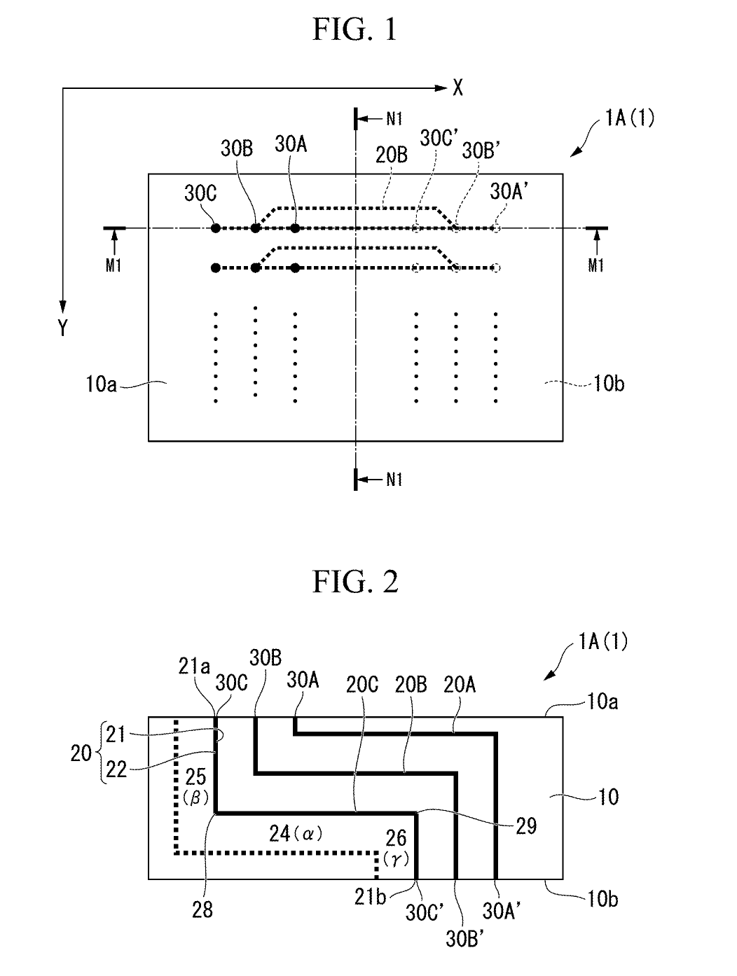

FIGS. 1 to 4 schematically show a configuration example of an interposer substrate of the first embodiment of the invention.

Here, FIG. 1 is a plan view illustrating a state where a plurality of terminal groups are arranged on a top face in the interposer substrate of the first embodiment of the invention.

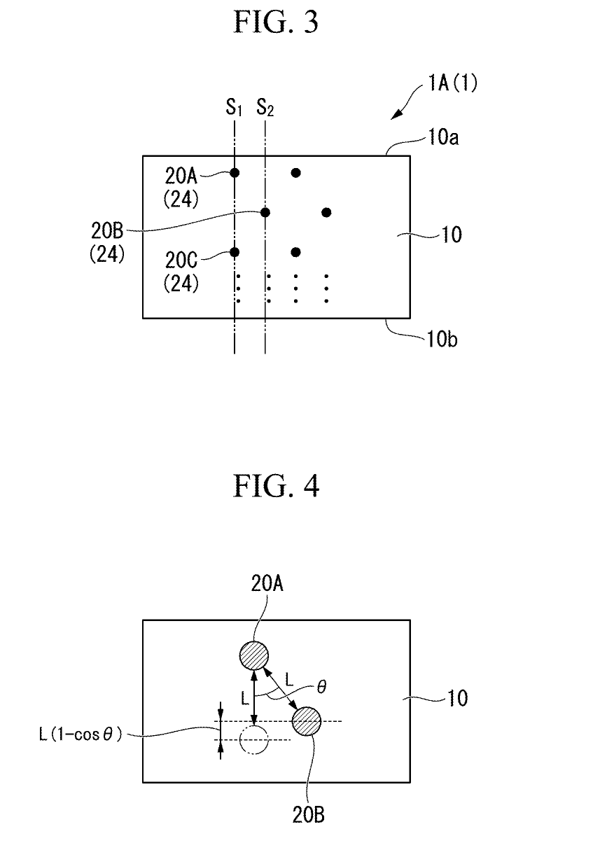

Additionally, FIG. 2 is a cross-sectional view taken along the line M1-M1 shown in FIG. 1, and FIGS. 3 and 4 are cross-sectional views taken along the line N1-N1 shown in FIG. 1.

An interposer substrate 1A (1) is provided with a plurality of through-hole interconnections 20A, 20B, and 20C (20) which connect main surfaces (the first main surface 10a and the second main surface 10b) constituting a single the substrate 10.

As a material used to form the substrate 10, an insulator such as glass, plastic, ceramics, or the like, a semiconductor such as silicon (Si) or the like is adopted.

In a case where a semiconductor substrate is used as a material used to form the substrate 10, it is desirable that insulating layers be formed on inner walls, main surfaces, or the like of through holes 21, and electrical insulation between the through-hole interconnections 20 and the substrate 10 be ensured.

In a case where an insulating substrate is used as a material used to form the substrate 10, since insulating layers are not further formed on the inner walls of the through holes 21, it is more preferable.

A conductor 22 is disposed inside the through hole 21 having a first opening portion 21a opening at one face 10a (first main surface) of main surfaces of the substrate 10 and a second opening portion 21b opening at the other main face 10b of the main surfaces (second main surface) of the substrate 10.

The through-hole interconnection 20 is constituted of the conductor 22.

The through-hole interconnection 20 is constituted of a first portion 24 (portion α), a second portion 25 (portion β), and a third portion 26 (portion γ).

The first portion 24 is formed inside the substrate 10 while extending so that the longitudinal direction of the first portion 24 is substantially parallel to the main surface of the substrate 10.

The second portion 25 and the third portion 26 are positioned at both ends of the first portions 24, respectively.

In other words, the second portion 25 forms a first end portion (one of end portions) of the through-hole interconnection 20, and the third portion 26 forms a second end portion (the other of end portions) of the through-hole interconnection 20.

That is, the end portion (first end portion) of the second portion 25 is located at the first main surface 10a (exposed to space facing the first main surface 10a), and the end portion (second end portion) of the third portion 26 is located at the second main surface 10b (exposed to space facing the second main surface 10b).

The first portion 24 and the second portion 25 are connected at a bend portion 28.

The first portion 24 and the third portion 26 are connected at a bend portion 29.

The configurations of the bend portions 28 and 29 are not particularly limited.

The bend portions may be a configuration having a corner in the vertical cross section thereof.

Alternatively, a substantially arc shape not having a corner may be used.

In terms of high-speed transmission, a substantially arc-shaped bend portion not having a corner is more preferably used.

Moreover, it is preferable that the longitudinal directions of the second portion 25 and the third portion 26 be substantially perpendicular to the main surfaces 10a and 10b, respectively.

The longitudinal direction of the second portion 25 is substantially vertical to the first main surface 10a, and the longitudinal direction of the third portion 26 is substantially vertical to the second main surface 10b.

Because of this, even in cases where the substrate 10 has variations in the initial thickness thereof or variations in thickness in terms of processing accuracy in a process of polishing a substrate 10 occur, the positions of the opening portions 21a and 21b provided on the main surfaces of the substrate 10 do not vary.

By means of this structure, it is possible to reliably form the through-hole interconnections 20 with a high level of accuracy.

As the conductors 22 used for the through-hole interconnections 20, conductors can be adopted made of a metal such as copper (Cu), tungsten (W), or the like; alloys such as gold-tin (Au—Sn) or the like; or non-metals such as polysilicon or the like.

As a method of filling through holes 21 with conductors or a method of forming conductors, a plating method, a sputtering method, a molten metal filling method, a chemical vapor deposition, a supercritical fluid deposition method, or the like can be adequately used.

In the interposer substrate 1A (1), a plurality of terminal groups are arranged on the surface thereof.

Terminals arranged on the first main surface 10a of the substrate 10 (the first main surface 10a side) are electrically connected to terminals arranged on another second main surface 10b of the substrate 10 (the second main surface 10b side) through the through-hole interconnections 20.

For example, as shown in FIGS. 1 and 2, first terminal groups 30A, 30B, and 30C which align at regular intervals are disposed on the first main surface 10a of the substrate 10.

Second terminal groups 30A′, 30B′, and 30C′, whose positions in the second main surface 10b are different from that of the first terminal groups in the X direction, are disposed on the second main surface 10b of the substrate 10 with the same layout as that of the first terminal groups.

Consequently, the first terminal groups 30A, 30B, and 30C are electrically connected to the second terminal groups 30A′, 30B′, and 30C′ through the through-hole interconnections 20A, 20B, and 20C so that the terminal numbers thereof correspond to each other.

That is, the first terminal 30A is electrically connected to the second terminal 30A′ through the through-hole interconnection 20A.

Additionally, the first terminal 30B is electrically connected to the second terminal 30B′ through the through-hole interconnection 20B.

Furthermore, the first terminal 30C is electrically connected to the second terminal 30C′ through the through-hole interconnection 20C.

Subsequently, as shown in FIG. 3, the through-hole interconnections 20A, 20B, and 20C (20) adjacent to each other are provided in the interposer substrate 1A (1) of the first embodiment of the invention so that ideal axes S1 and S2, which extend perpendicular to the main surface of the substrate 10 (the first main surface 10a and the second main surface 10b) and penetrate through the centers of the first portions 24, are parallel to each other and separated from each other.

Here, a plurality of the axes S1 and S2 are assumed axes in the interposer substrate 1A (1).

In addition, FIG. 3 shows a horizontal cross-sectional face of the first portion 24, and the ideal axes S1 and S2 penetrate through the centers in the horizontal cross-sectional face of the first portion 24.

Hereinbelow, in order to explain a positional relationship between the adjacent through-hole interconnections, the relationship between the through-hole interconnection 20A and the through-hole interconnection 20B will be described.

For example, as shown in FIG. 3, the axis S1 (ideal axis) of the through-hole interconnections 20A and the axis S2 (ideal axis) of the through-hole interconnections 20B are parallel to each other with a distance therebetween.

Particularly, in the interposer substrate 1 of the first embodiment of the invention, the through-hole interconnections 20A and 20B are arranged so that at least the positions of the adjacent through-hole interconnections 20A and 20B are displaced from each other.

As shown in an enlarged cross-sectional view of FIG. 4, the through-hole interconnection (20B) which is one of the adjacent through-hole interconnections 20A and 20B is located so as to be displaced from the direction perpendicular to the main surface by the angle θ.

Here, the diameters R of the through-hole interconnections 20A and 20B are constant.

Moreover, the distance by which the adjacent through-hole interconnections 20A and 20B are separated (the distance by which the adjacent edges of the through-hole interconnections adjacent to each other are separated) is represented as L, and this distance is constant.

At this time, the through-hole interconnection 20B is provided at the position which is displaced from the direction perpendicular to the main surface while the distance between the adjacent through-hole interconnections 20A and 20B is maintained.

The length in the thickness direction of the substrate 10 (the direction perpendicular to the main surface) is reduced by (1−cos θ) L in appearance.

For this reason, as compared with the structure (the structure in which the adjacent through-hole interconnections 20A and 20B arranged in the vertical direction) in which through-hole interconnections align so as not to be displaced from the direction perpendicular to the main surface so that the through-hole interconnections 20 having the same number as that of the embodiment are separated from each other at the same distance L, it is possible to suppress an increase in the thickness of the substrate 10.

As a result, in the first embodiment of the invention, even if the number of through-hole interconnections increases, an increase in the thickness of the substrate can be suppressed, it is possible to realize three-dimensional packaging with high-density or make an electronic device package thinner.

### Second Embodiment

Next, a second embodiment of the invention will be described.

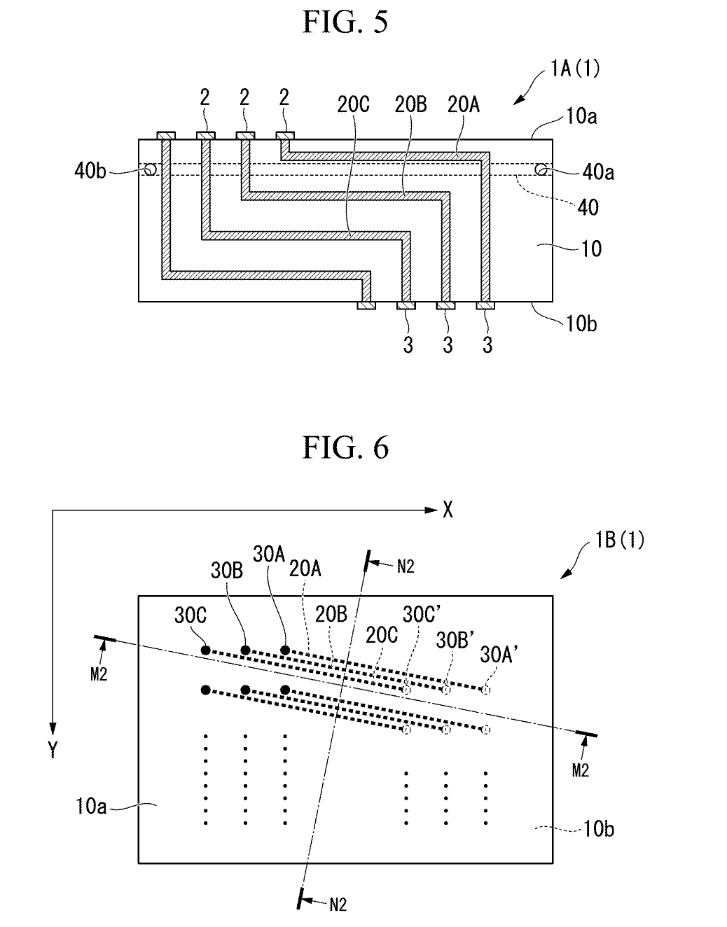

Additionally, in the interposer substrate 1A (1) of a second embodiment as shown in FIG. 5, pads 2 and 3 may be provided on the main surfaces 10a and 10b of the substrate 10, respectively, so as to electrically connect the second portion 25 and the third portion 26 constituting the through-hole interconnection 20.

When the devices are mounted onto both faces of the interposer substrate 1A (1), even in cases where a downsized device in which the electrodes are densely arranged with any layout is used, since the electrodes of the devices and the pads are electrically connected to each other without front wirings, a downsized device can be connected to the interposer substrate.

Furthermore, in the interposer substrate 1A (1), the lengths of the through-hole interconnections 20A, 20B, and 20C are preferably substantially the same as each other.

Because of this, the electrical resistances of the through-hole interconnections 20A, 20B, and 20C can be made substantially uniform, and it is possible to improve the electrical characteristics of the device mounted onto the interposer substrate 1A (1).

Additionally, it is possible to reduce a malfunction such as variations in the wiring delay of the through-hole interconnections in high-speed signal transmission.

### Third Embodiment

Next, a third embodiment of the invention will be described.

Additionally, in the interposer substrate 1A (1), the substrate 10 may include a cooling unit cooling the substrate 10.

As such cooling unit cooling the substrate 10, for example, a flow passage 40 allowing a cooling fluid to flow therein is adopted as shown in FIG. 5.

By means of this structure, even in cases where a device having a large amount of heat generation is mounted onto the interposer substrate, an increase in temperature can be reduced by applying a cooling medium to the flow passage 40.

The flow passage 40 includes outlet-inlet ports 40a and 40b which are provided at both ends of the flow passage 40 and which discharge and supply the cooling fluid.

For example, a plurality of flow passages 40 may be provided.

Furthermore, the flow passage 40 may be provided so as to wind its way so that a single flow passage 40 can cool over the entirety of the substrate 10.

Additionally, the outlet-inlet ports 40a and 40b of the flow passage 40 may open at the main surface of the substrate 10.

Moreover, the pattern (pathway) or the cross-sectional shape of the flow passage 40 is not limited to the aforementioned structure and can be appropriately designed.

However, it is preferable that the flow passage 40 itself maintain a predetermined distance from the through hole 21 in a direction three-dimensionally parallel to the surface or in the thickness direction so as not to communicate with the through hole having the through-hole interconnection 20.

The flow passage 40 can be formed by the same method as the method of forming the through holes 21 in which the through-hole interconnections 20 are to be disposed.

At this time, when the through holes 21 in which the through-hole interconnections 20 are to be formed are formed, a through hole serving as the flow passage 40 is preferably formed collaterally and simultaneously.

By simultaneously forming the through holes 21 of the through-hole interconnections 20 and the through hole used as the flow passage 40, a manufacturing process therefor can be simplified and the cost therefor can be reduced.

In addition, positional relationships between the through holes 21 and the flow passage 40 can be easily controlled, and it is possible to prevent the through holes 21 and the flow passage 40 from being incorrectly communicated with each other.

### Fourth Embodiment

Next, a fourth embodiment of the invention will be described.

The invention is applicable to the structure in which, the arrangements of a plurality of terminals on the substrate surface in the view point of the vertical direction of a first main surface and a second main surface are different not only in the X-axial direction but also in the Y-axial direction.

Here, FIG. 6 is a plan view illustrating a state where a plurality of terminal groups are arranged on a top face in the interposer substrate 1B (1) of the fourth embodiment of the invention.

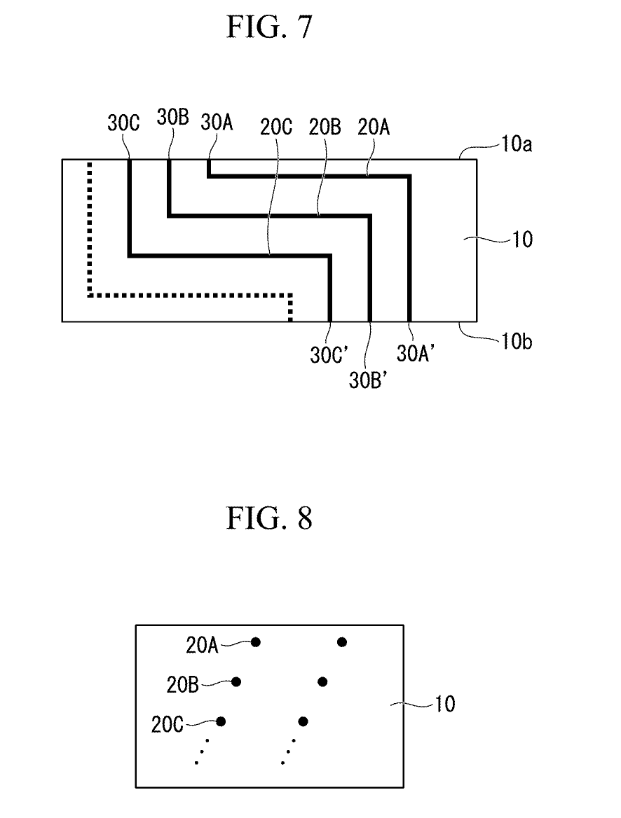

Additionally, FIG. 7 is a cross-sectional view taken along the line M2-M2 shown in FIG. 6, and FIG. 8 is a cross-sectional view taken along the line N2-N2 shown in FIG. 6.

In the interposer substrate 1B (1) of the fourth embodiment, the arrangement of the through-hole interconnections shown in FIGS. 6 and 8 is not the arrangement (refer to FIG. 1) such that one of through-hole interconnections goes around the other of through-hole interconnections as seen from the vertical direction of the first main surface and the second main surface.

Specifically, the adjacent through-hole interconnections 20A, 20B, and 20C extend so as to be oblique to the X-axial direction and the Y-axial direction.

Accordingly, the adjacent through-hole interconnections 20A, 20B, and 20C are arranged so as to be displaced from each other (inevitably).

For this reason, as shown in FIG. 8, by only forming the through-hole interconnections in the substrate 10 in a desired depth in the vertical direction thereof, it is possible to realize the interposer substrate 1B (1) of the fourth embodiment of the invention.

Furthermore, as shown in FIG. 1, since the constitution in which one through-hole interconnection is disposed so as to go around the other through-hole interconnection is not used, it is possible to connect the first main surface and the second main surface by the distance shorter than that of the through-hole interconnection shown in FIG. 1.

Next, a method of manufacturing the above-described interposer substrate 1A (1) will be described.

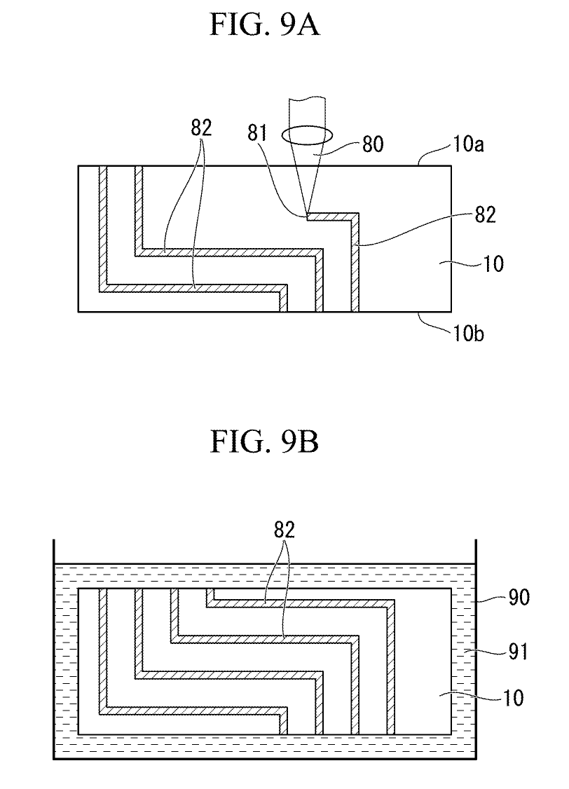

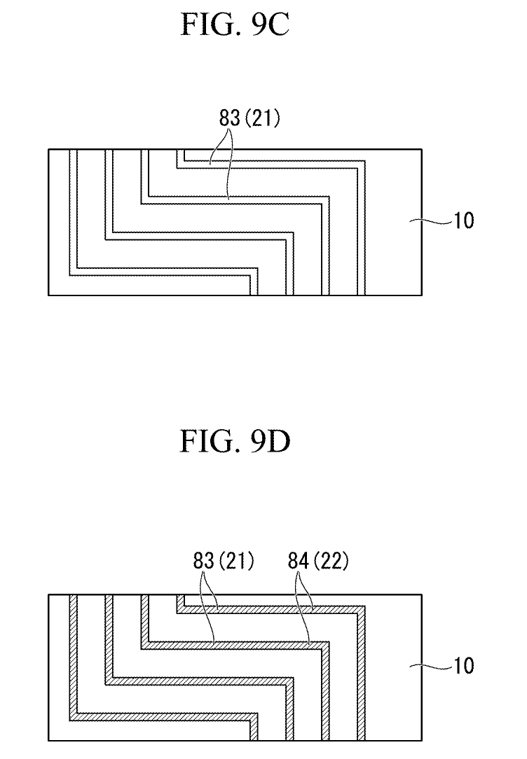

FIGS. 9A to 9D are cross-sectional views schematically showing a manufacturing method of the interposer substrate 1A (1) in the order of steps thereof.

In the embodiment, as a base material, a glass substrate (silica) having a thickness of 500 μm is used.

In addition, a manufacturing method of a microscopic hole in the embodiment modifies part of a silica substrate using a laser, thereafter, remove the modified portion by etching.

Firstly, as shown in FIG. 9A, modified regions 82 are formed inside the substrate 10 by irradiating, with a laser light 80, the portion on the substrate 10 made of silica, on which at least microscopic hole are to be formed in a subsequent step.

In the embodiment, a femtosecond laser is used as a light source of the laser light 80, the inside of the substrate 10 is irradiated with laser beam so that a focal point 81 is focused therein, and modified regions are obtained which have a diameter of, for example, several μm to dozens of μm.

At this time, it is possible to form modified regions 82 having various configurations by controlling the focal point 81 and the substrate position.

In other cases, the substrate 10, in which microscopic holes are to be formed, is not limited to a silica substrate, and as the substrate, for example, an insulative substrate 10 such as sapphire or the like or a glass substrate having other components containing an alkaline component or the like may be used.

Also, the thickness of the glass substrate is set to appropriately in the range of approximately 150 μm to 1 mm.

Subsequently, as shown in FIG. 9B, the substrate 10 in which the modified regions 82 are formed is immersed in a predetermined chemical solution 91 contained in a container 90.

Consequently, the modified regions 82 are wet-etched by the chemical solution and are removed from the inside of the substrate 10.

As a result, as shown in FIG. 9C, the microscopic hole 83 (the through hole 21) is formed at the portion at which the modified region 82 was present before.

In the embodiment, as the chemical solution, an acid solution containing hydrofluoric acid as a main component is used.

The etching used in this embodiment utilizes a phenomenon that the modified region 82 is etched extremely faster than non-modified portion, it is possible to finally form a microscopic hole 83 having the configuration which is caused by the modified region 82.

In the embodiment, the hole diameter of the microscopic hole 83 is 50 μm.

In other cases, the chemical solution is not limited to hydrofluoric acid. For example, a mixed acid or the like containing hydrofluoric-nitric acid system in which an appropriate amount of nitric acid or the like is added into hydrofluoric acid, or an alkaline solution or the like such as potassium hydroxide solution can be used.

Furthermore, the hole diameter of the microscopic hole can be appropriately set in the range of approximately 10 to 300 μm depending on the intended use of the through-hole interconnection.

Moreover, the microscopic hole 83 formed by the aforementioned method is not limited to a “through hole” penetrating through the substrate 10 and may be a “non-penetration hole” not penetrating through the substrate 10.

According to the aforementioned method, it is possible to form microscopic holes 83 having a three-dimensional free structure in the substrate 10 made.

After that, as shown in FIG. 9D, the insides of the microscopic holes 83 are filled with electroconductive substance 84 (conductors 22).

In the embodiment, gold-tin (Au—Sn) is used as the electroconductive substance 84 (conductors 22), and the insides of the microscopic holes are filled with that by a molten metal filling method.

The molten metal filling method is a method which can fill the insides of the microscopic holes with that by action of a pressure difference with a high level of airtightness in a short amount of time.

Additionally, gold-tin (Au—Sn) is used as a metal filler in the embodiment, it is not limited thereto.

A metal such as gold-tin alloy containing different compositions, tin (Sn), indium (In), or the like, or a solder such as a tin lead (Sn—Pb) based solder, a tin (Sn) based solder, a lead (Pb) based solder, a gold (Au) based solder, an indium (In) based solder, an aluminum (Al) based solder, or the like, may be used.

Additionally, a molten metal suction method is used as a filling method in the above description, but it is not limited to this method, metal filling or metal film formation by a plating method, chemical vapor deposition, or a supercritical fluid deposition method; filling of electroconductive paste by a printing method; and a method in which such methods are combined can be adequately used.

It is possible to provide the interposer substrate 1A (1) including a plurality of the through-hole interconnections 20 by the above-described method.

In addition, the structure in which the microscopic holes 83 penetrate through the main surface the substrate 10 is adopted in the above-described embodiment, but the invention is not limited to this structure.

For example, non-penetrated microscopic holes 83 are preliminarily formed on the substrate 10, the microscopic holes are filled with metal, thereafter, the through-hole interconnections 20 can also be formed by polishing the substrate 10.

(Electronic Device Package)

Next, an electronic device package using the interposer substrate 1A (1) the above-described invention will be described.

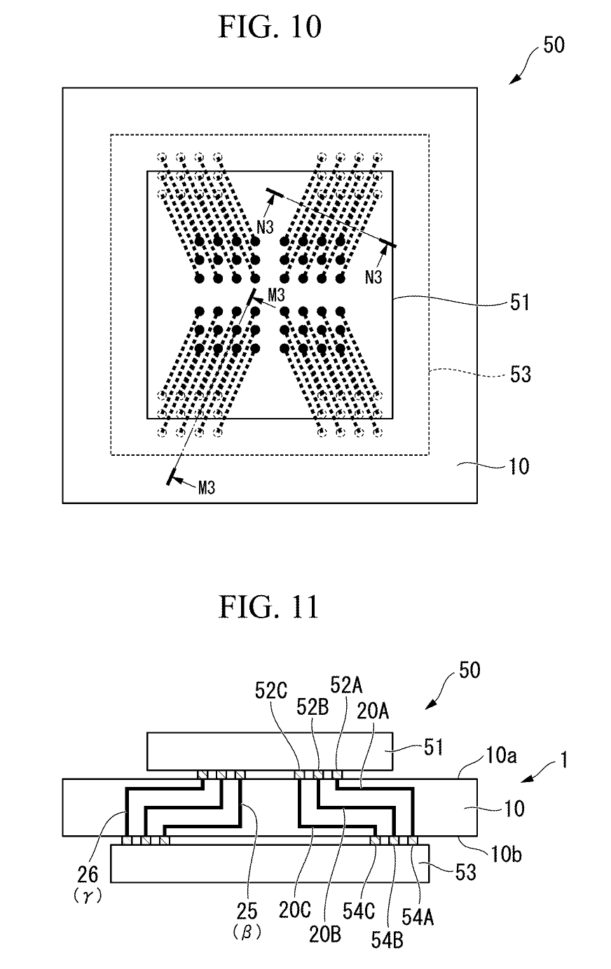

FIGS. 10 to 12 are plan views schematically showing an embodiment (configuration example) of an electronic device package related to the invention.

Additionally, FIG. 11 is a cross-sectional view taken along the line M3-M3 shown in FIG. 10.

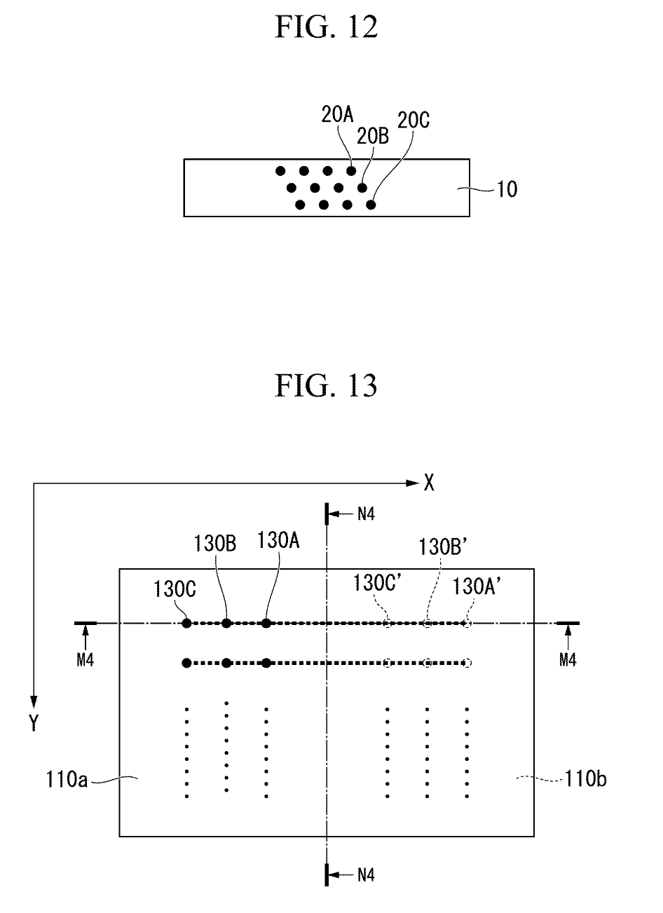

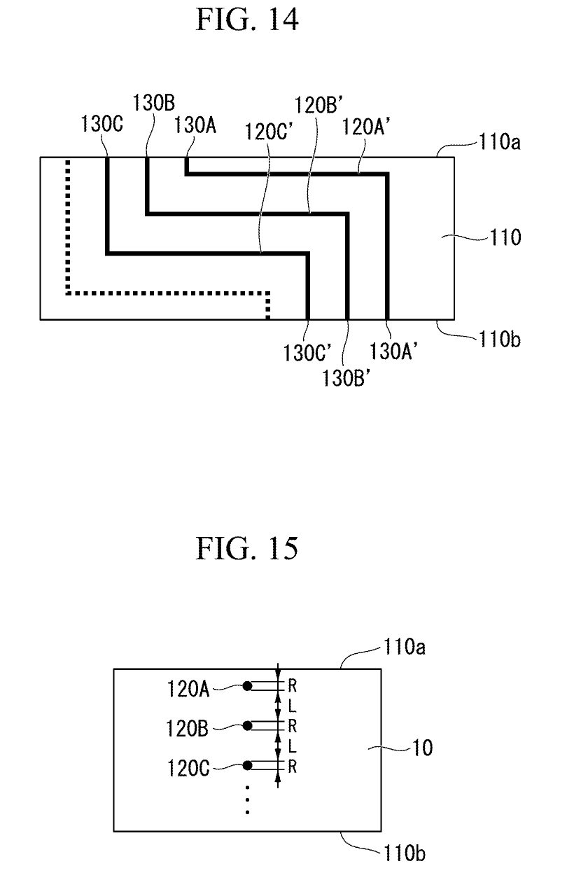

FIG. 12 is a cross-sectional view taken along the line N3-N3 shown in FIG. 10.

In the electronic device package 50, the electronic device is mounted onto at least one of the main surfaces of the interposer substrate 1.

As described above, since at least the adjacent through-hole interconnections 20 are arranged so as to be displaced from each other in the interposer substrate 1, an increase in the thickness of the substrate 10 can be suppressed even where the number of the through-hole interconnections increases.

For this reason, it is possible to make an electronic device including the electronic device package thinner, and to realize downsizing thereof, speeding up thereof, or the like.

The electronic device package 50 is provided with the interposer substrate 1 having the through-hole interconnections 20 in which the through holes 21 formed on the substrate 10 is filled or formed with the conductors; a first device 51 disposed on the first main surface 10a of the substrate 10; and a second device 53 disposed on near the second main surface 10b of the substrate 10.

The arrangement of electrodes of the first device 51 and the arrangement of electrodes of the second device 53 are different from each other.

By use of the interposer substrate 1, electrodes 52A, 52B, and 52C of the first device 51 disposed on the first main surface 10a of the substrate 10 and electrodes MA, 54B, and 54C of the second device 53 disposed on the second main surface 10b of the substrate 10 are electrically connected, respectively, with the through-hole interconnections 20A, 20B, and 20C interposed therebetween.

An integrated circuit (IC) such as a memory (storage element), a logic (logical element), or the like, a MEMS device such as a sensor or the like, an optical device such as a light-emitting element, a light receiving element, or the like is adopted as the devices 51 and 53.

As long as the arrangement of electrodes of the devices 51 and 53 are different from each other, the functions of the devices 51 and 53 may be different from each other or the same as each other.

Particularly, it is possible to realize three-dimensional system in package (SiP) by high-densely integrating different kinds of devices thereinto.

Furthermore, as shown in FIG. 11, in the electronic device package 50, at least one of the exposed end portion of the second portion 25 and the end portion of the third portion 26 is disposed at a position facing the electrodes 52 and 54 of the devices 51 and 53 which are to be mounted.

It is preferable that the electrodes of the devices 51 and 53 be electrically connected to at least one of the end portion of the second portion 25 and the end portion of the third portion 26.

As a result, even in cases where a downsized device in which the electrodes are densely arranged with any layout is used, since the electrodes 52 (52A, 52B, 52C) of the device 51 and the electrode 54 (54A, 54B, 54C) of the device 53, which are mounted onto both faces of the interposer substrate 1, are electrically connected to each other without front wirings, it is possible to freely connect the electrodes 52 and the electrodes 54.

(Electronic Component)

An electronic component related to the invention is provided with at least the above-described the electronic device package 50 of the invention.

As a result, it is possible to make an electronic device (electronic component) including the electronic device package thinner, and to realize downsizing thereof, speeding up thereof, or the like.

In the above-description, the interposer substrate, the electronic device package, and the electronic component of the invention are described, the technical scope of the invention is not limited to the above embodiments, and various modifications may be made without departing from the scope of the invention.

### INDUSTRIAL APPLICABILITY

The invention is widely applicable to an interposer substrate including through-hole interconnections, and an electronic device package using this, and an electronic component.

What is claimed is:

1. An interposer substrate comprising:
a single substrate having a first main surface and a second main surface; and
a plurality of through-hole interconnections having first portions formed so as to extend in parallel with each other and connecting the first main surface to the second main surface, wherein
the through-hole interconnections adjacent to each other are provided so that ideal axes are parallel to each other with a distance therebetween, and the ideal axes extend perpendicular to at least one of the first main surface and the second main surface and penetrate through centers of the first portions.

2. The interposer substrate according to claim 1, wherein
the first portions are located substantially parallel to at least one of the first main surface and the second main surface.

3. The interposer substrate according to claim 1, wherein
the through-hole interconnections have second portions and third portions forming both ends of the first portions,
longitudinal directions of the second portions is substantially perpendicular to the first main surface, and
longitudinal directions of the third portions is substantially perpendicular to the second main surface.

4. The interposer substrate according to claim 1, wherein
lengths of the through-hole interconnections are the same as each other.

5. The interposer substrate according to claim 1, further comprising:
pads provided on the first main surface so as to be electrically connected to the second portions constituting the through-hole interconnections; and
pads provided on the second main surface so as to be electrically connected to the third portions constituting the through-hole interconnections.

6. The interposer substrate according to claim 1, wherein
the substrate comprises a cooling unit cooling the substrate.

7. An electronic device package comprising:
the interposer substrate according to claim 1; and
an electronic device mounted onto at least one of the first main surface and the second main surface of the interposer substrate.

8. The electronic device package according to claim 7, wherein
the through-hole interconnections of the interposer substrate have second portions and third portions forming both ends of the first portions,
at least one of an end portion of the second portions and an end portion of the third portions is located at a position facing a terminal of the electronic device, and
the terminal of the electronic device is electrically connected to at least one of the end portions of the second portions and the third portions.

9. An electronic component comprising the electronic device package according to claim 7.
